(19) United States
(12) Patent Application Publication
(10) Pub. No.: US 2006/0269656 A1
(43) Pub. Date: Nov. 30, 2006

(54) Reducing contamination in OLED processing systems

(75) Inventors: Michael L. Boroson, Rochester, NY (US); Anatole Pleten, Brockport, NY (US); Steven A. Van Slyke, Pittsford, NY (US); Terrence R. O'Toole, Webster, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/138,928

(22) Filed: May 26, 2005

(51) Int. Cl. B05D 5/12; C23C 16/00

(52) U.S. Cl. 427/66; 427/248.1

(57) ABSTRACT

A method of vaporizing organic material for deposition of an organic layer on a substrate for use in making an OLED device includes providing a first vacuum chamber, vaporizing gettering material to coat a surface which is in or to be placed in the first vacuum chamber or in a second vacuum chamber, and vaporizing the organic material to deposit vaporized organic material on the substrate and leaving the substrate in the first chamber or moving it to the second chamber, whereby the gettering material reacts with contaminants to lessen incorporation of contaminants into the OLED device.

### FIELD OF THE INVENTION

The present invention relates to making organic light-emitting diode (OLED) displays in a manufacturing apparatus.

### BACKGROUND OF THE INVENTION

OLED displays are one of the most recent flat panel display technologies and are predicted to overtake LCD display technology for certain applications within the next decade. OLED displays offer brighter displays, significantly wider viewing angles, lower power requirements, and longer lifetimes than their LCD counterparts. OLED technology offers more display flexibility and alternatives to backlit LCD displays. For example, OLED displays can be made of thin, flexible materials that conform to any desired shape for specific applications. However, OLED displays and their components known as OLED structures, which constitute subpixels of the display, are more difficult and costly to make than LCD displays. It is a continuing focus of the industry to increase throughput in an effort to lower the cost of OLED manufacturing.

Conventional OLED display devices are built on glass substrates in a manner such that a two-dimensional OLED array for image manifestation is formed. The basic OLED cell structure includes a stack of thin organic layers sandwiched between one or more anode(s) and one or more metallic cathode(s). The organic layers typically comprise a hole transport layer (HTL), an emissive layer (EL), and an electron transport layer (ETL). When an appropriate voltage is applied to the cell, the injected holes and electrons recombine in the emissive layer near the EL-HTL interface to produce light (electroluminescence). In conventional OLED device manufacturing, linear or point source vacuum deposition processes are used to deposit the organic materials on to the substrate.

These OLED organics are particularly susceptible to damage from environmental exposure, such as moisture, oxygen, and ultraviolet light, and from low levels of organic and inorganic contaminants, such as phthalates and halogen-containing compounds. In research or small-scale process equipment, environmental exposure and contamination is reduced when the entire OLED device is prepared in a single vacuum chamber. However, this type of preparation does not have sufficient throughput for large-scale lower-cost manufacturing. For such process equipment, a series of controlled-environment chambers is one solution envisioned, wherein each layer of the device is formed in a dedicated chamber. Such a process increases the likelihood of environmental exposure and contamination during manufacture. The challenge is to integrate the various processes to produce a scalable manufacturing system that is cost effective and that reduces contamination of the OLED device.

Conventional OLED process equipment uses vacuum systems to maintain the environments of the process chamber(s). Diffusion pumps and cryogenic pumps are the most common types of pumps used in OLED processing. These pumps are typically used on OLED vacuum systems to achieve base pressures in the 10⁻⁵ to 10⁻⁷ Torr range. Cleaning of vacuum equipment to reduce contamination is a known requirement in many types of vacuum processes. Common cleaning methods used in vacuum processing include solvent cleaning and baking, ozone pretreatment, and plasma pretreatment. For plasma pretreatment, both oxidizing plasmas and reducing plasmas and combinations of oxidizing and reducing plasmas are used. The cleaning effect of solvent washing and baking, ozone pretreatment, or plasma pretreatment, however, ends with the treatment; therefore, these cleaning methods will not be effective against contamination introduced during the manufacturing process from contamination sources within the process equipment.

### SUMMARY OF THE INVENTION

It is therefore an object of the present invention to reduce contamination and improve performance of OLED devices prepared in a manufacturing process.

This object is achieved by a method of vaporizing organic material for deposition of an organic layer on a substrate for use in making an OLED device, comprising:

a) providing a first vacuum chamber;

b) vaporizing gettering material to coat a surface which is in or to be placed in the first vacuum chamber or in a second vacuum chamber; and

c) vaporizing the organic material to deposit vaporized organic material on the substrate and leaving the substrate in the first chamber or moving it to the second chamber, whereby the gettering material reacts with contaminants to lessen incorporation of contaminants into the OLED device.

### ADVANTAGES

It is an advantage of the method of this invention that it can produce an OLED device with lower contamination and better performance, such as improved lifetime.

It is another advantage of this invention that the improved OLED device is produced in a multi-chamber or multi-station manufacturing tool, thus permitting high throughput without a reduction in device performance.

It is a further advantage of this invention that lower contamination levels are maintained within the manufacturing tool without interrupting the manufacturing process and without requiring separate maintenance time.

It is a still further advantage of this invention that lower contamination levels are maintained within the manufacturing tool even when contamination sources are within the manufacturing tool.

### BRIEF DESCRIPTION OF THE DRAWINGS

FIG. 1 is a cross-sectional view of a first embodiment of a vacuum chamber and an apparatus that are used in accordance with the present invention;

FIG. 2 is a block diagram showing the steps involved in one embodiment of a method according to the present invention;

FIG. 3 is a cross-sectional view of another embodiment of a vacuum chamber and an apparatus that are used in accordance with the present invention;

FIG. 4 is a schematic of a manufacturing system comprising a series of vacuum chambers that are used in accordance with this invention:

FIG. 5 is a cross-sectional view of an OLED device structure that is prepared with the present invention;

FIG. 6 is a cross-sectional view of an embodiment of multiple vacuum chambers and an apparatus that are used in accordance with the present invention;

FIG. 7 is a block diagram showing the steps involved in another embodiment of a method according to the present invention;

FIG. 8 is a cross-sectional view of another embodiment of multiple vacuum chambers and all apparatus that are used in accordance with the present invention; and

FIG. 9 is a block diagram showing the steps involved in another embodiment of a method according to the present invention.

### DETAILED DESCRIPTION OF THE INVENTION

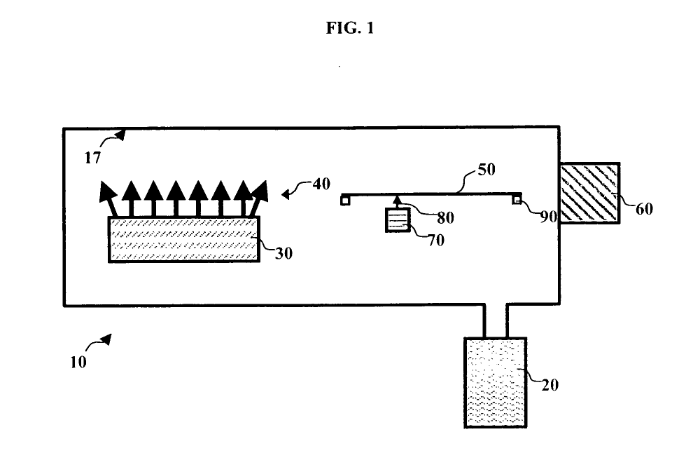

Turning now to FIG. 1, there is shown a cross-sectional view of a first embodiment of a vacuum chamber and an apparatus that are used in accordance with the present invention for deposition of an organic layer on a substrate for use in a method for making an OLED device. First vacuum chamber 10 is an enclosed apparatus that permits a substrate 50 to be coated with vaporized organic material 80 in an environment wherein a gettering material reacts with contaminants to lessen incorporation of such contaminants into an organic layer formed from the vaporized organic material. The contaminants of concern are typically low levels of organic and inorganic compounds. These contaminants include phthalates, halogen-containing compounds, and other compounds that decrease the performance of OLED devices by reacting with OLED materials or by acting as hole or electron traps within the OLED structure. The organic layer herein refers to one or more layers of an organic light-emitting diode (OLED) device.

First vacuum chamber 10 includes gettering material vaporizer 30, which is a way of vaporizing gettering material 40 in the vacuum chamber. Gettering material 40 is a reactive material for removing contamination and can include a reactive metal, including alkali metals such as lithium, sodium, potassium, or cesium; alkaline earth metals such as magnesium, calcium, or barium; or other reactive metals such as Al, Ti, Sc, Cr, Fe, Ni, Cu, Zn, or Ga, or a lanthanide series metal, or combinations thereof The preferred gettering material 40 includes reactive metals with a work function less than 5 eV. The most preferred gettering material 40 includes aluminum, alkali metals such as Li and Cs, and alkaline earth metals such as Mg, Ca, and Ba. In addition to being effective, such metals are often used in OLED devices for other purposes, so it is also convenient to select them as the gettering material. Another preferred gettering material 40 is Ti because titanium getter pumps are readily available. Titanium sublimation pumps are not typically used in OLED processing vacuum systems, but are used in ultra-high vacuum systems as secondary pumps to increase pumping speeds of oxygen, water, carbon monoxide, carbon dioxide, nitrogen, and hydrogen. There is no prior art to suggest that titanium sublimation pumps will reduce organic or inorganic contaminants in OLED processing vacuum systems to the levels needed for OLED device manufacturing. Gettering material vaporizer 30 is, e.g. a heated boat, a sputtering device, or other ways of providing gettering material 40 in a vaporized form. Gettering material 40 can then coat a surface in first vacuum chamber 10, such as the interior walls of the chamber. However, this method is not restricted to coating an interior wall of vacuum chamber 10 with gettering material. The gettering material can coat a structure provided for receiving gettering material coating within vacuum chamber 10, such as a plate located in a receiving position relative to gettering material vaporizer 30. Alternatively, the gettering material can coat a surface that is in a second vacuum chamber. Such a surface can remain in the second vacuum chamber, or is placed in the first vacuum chamber. These variations will be illustrated in alternate embodiments below.

First vacuum chamber 10 is held under vacuum by vacuum pump 20. The term “vacuum” is used herein to designate a pressure of 1 Torr or less. First vacuum chamber 10 includes load lock 60, which is used to load the chamber with uncoated substrates, and to remove the coated substrates. After gettering material 40 vaporizes and coats one or more surfaces in vacuum chamber 10, e.g. surface 17, gettering material vaporizer 30 is turned off and a substrate 50 placed in vacuum chamber 10. If necessary, substrate 50 is supported by supporting means, e.g. supports 90. Organic material vaporizer 70 can then vaporize organic material 80 so as to deposit an organic layer on substrate 50. The gettering material on surface 17 can react with contaminants in vacuum chamber 10 to lessen incorporation of contaminants into the OLED device prepared from substrate 50 while it is left in vacuum chamber 10. The nature of substrate 50, organic material 80, and organic material vaporizer 70 will be discussed in further detail below.

The apparatus can further comprise additional chambers, e.g. connected through load lock 60, for loading, unloading, or transporting substrate 50 into the corresponding vacuum chamber 10, or can comprise multiple chambers or coating locations connected in series for successively coating, pretreating, or processing substrate 50. Such additional chambers or coating locations can also include gettering material vaporizers for vaporizing gettering material so as to coat one or more surfaces in the respective additional chambers or coating locations and to lessen the incorporation of contaminants from those chambers or coating locations into the OLED device.

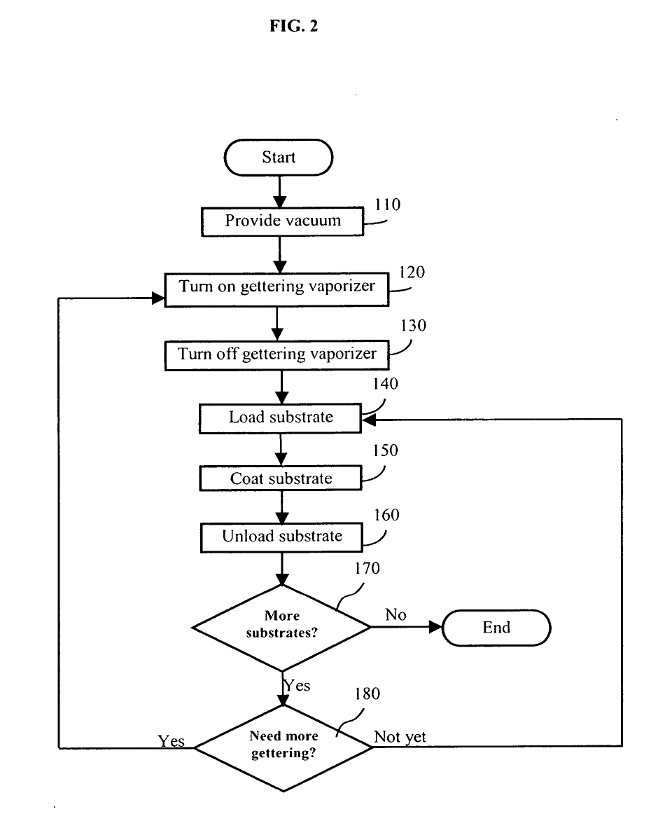

Turning now to FIG. 2, and referring also to FIG. 1, there is shown a block diagram showing the steps involved in a method of vaporizing organic material according to the present invention. At the start, a vacuum condition is provided by vacuum pump 20 in vacuum chamber 10 (Step 110). Gettering material vaporizer 30 is turned on (Step 120) to vaporize gettering material in vacuum chamber 10 and coat a surface or surfaces in vacuum chamber 10 with gettering material 40. Gettering material vaporizer 30 is then turned off (Step 130) and a substrate 50 is placed in vacuum chamber 10 through load lock 60 (Step 140). Organic material 80 is vaporized by organic material vaporizer 70 so as to deposit the vaporized organic material onto substrate 50 and form an organic layer (Step 150). During this process, the gettering material that has coated one or more surfaces in vacuum chamber 10 will react with contaminants so as to lessen the incorporation of those contaminants into the OLED device formed in part by vaporized organic material 80 on substrate 50. The reduction in contamination is on substrate 50, in the deposited organic layer, or both. The coated substrate can then be removed from vacuum chamber 10 through load lock 60 (Step 160). If no more substrates are to be coated (Step 170), the process ends.

If more substrates are to be coated (Step 170), two actions are possible (Step 180). If more gettering is necessary in vacuum chamber 10, gettering material vaporizer 30 is turned on again (Step 120) and the process continues. However, it is possible that a single gettering treatment will be sufficient for a number of substrate coatings, in which case a new substrate 50 is loaded into vacuum chamber 10 and the process continues. In such a case, the gettering treatment will be repeated after a predetermined number of substrate coatings that will depend on a number of factors, including the length and nature of the gettering treatment, the nature of the substrate and organic material, and other factors familiar to those skilled in the art.

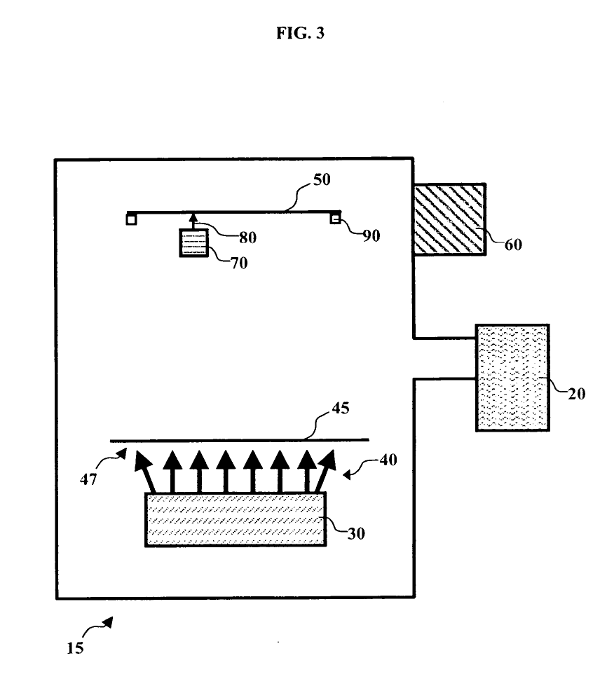

Turning now to FIG. 3, there is shown a cross-sectional view of another embodiment of a vacuum chamber and an apparatus that is used in accordance with the present invention. Vacuum chamber 15 is much like vacuum chamber 10 described above, except that it is arranged so that plate 45 is between gettering material vaporizer 30 and substrate 50. Gettering material 40 coats a surface 47 of plate 45 in vacuum chamber 15, and this prevents gettering material 40 from reaching substrate 50. Therefore gettering material 40 can continue to be vaporized during the vapor deposition of organic material 80. The gettering material on surface 47 can react with contaminants in vacuum chamber 15 to lessen incorporation of contaminants into the OLED device prepared from substrate 50. An advantage of this embodiment is that the coating of substrates 50 is not delayed for gettering material 40 vaporization.

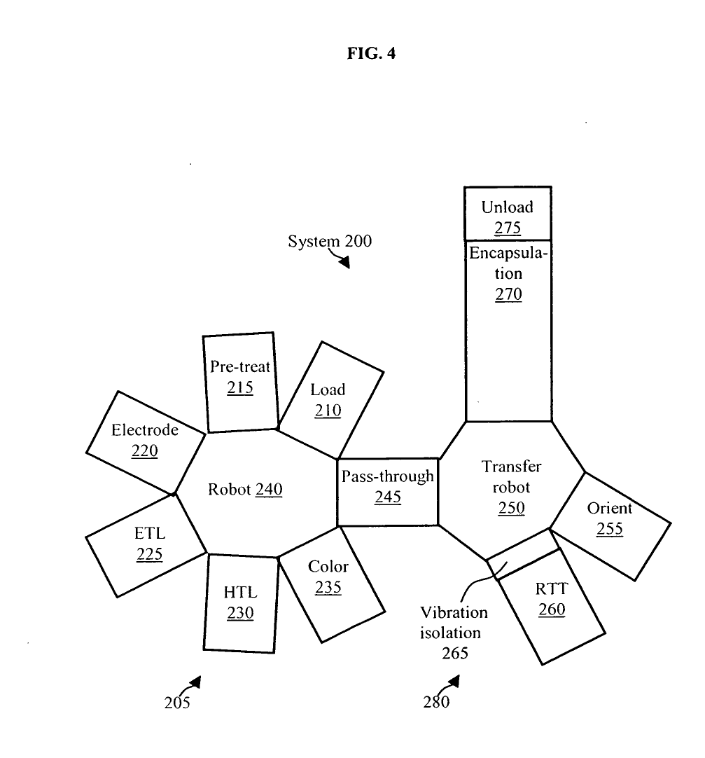

FIG. 4 illustrates a multi-chamber system 200 for making OLED display devices under a controlled environment wherein this invention is used. System 200 includes a cluster of two or more vacuum chambers. System 200 includes first cluster 205 and second cluster 280. First cluster 205 includes first robot 240 and the surrounding stations. Second cluster 280 includes second robot 250 and the surrounding stations. Each station is an individual controlled atmosphere coater or vacuum coater.

System 200 includes several different types of vacuum chambers. A first type of vacuum chamber coats organic materials. This type of chamber includes first station 230 that coats a hole-transporting layer, an emissive layer coating station 235 that coats a light-emitting layer, and third station 225 that coats an electron-transporting layer. Also included is second station 260 that is used to transfer an organic layer by a radiation thermal transfer process from a donor sheet and can optionally include vibration isolation element 265. Any of these chambers can include an apparatus as described above for vaporizing gettering material to coat a one or more surfaces in the chamber with a gettering material, either simultaneously with the organic-material coatings as in FIG. 3 or between coatings as in FIG. 1. Organic material is vaporized in these gettering-treated vacuum chambers to deposit vaporized organic material on a substrate to form an organic layer, while the deposited gettering material reacts with contaminants in the vacuum chambers to lessen incorporation of contaminants into the OLED device.

System 200 can further include chambers designed for loading, unloading, or transporting the substrate between corresponding coating chambers. This type of station includes loading station 210, first robot 240, pass-through 245 for moving the substrate between first cluster 205 and second cluster 280, second robot 250, orientation station 255, and unloading station 275. These chambers are also a potential source of contamination. One or more of these chambers can include an apparatus as described above wherein gettering material is vaporized in those chambers to coat interior portions of the chambers to lessen incorporation of contaminants into the OLED device.

A third type of station is pretreatment station 215. This is an organic deposition chamber (similar to first station 230, emissive layer coating station 235, or third station 225), a plasma chamber for oxygen, argon, or nitrogen plasma, or a plasma chamber for depositing a CFₓlayer. Pretreatment station 215 can include an apparatus as described above wherein gettering material is vaporized in the chamber to coat surfaces in pretreatment station 215 to lessen incorporation of contaminants into the OLED device, especially if this station is an organic deposition chamber.

System 200 can also include other stations necessary for OLED manufacturing, e.g. fourth station 220 for coating an electrode, and encapsulation station 270 for sealing the OLED device.

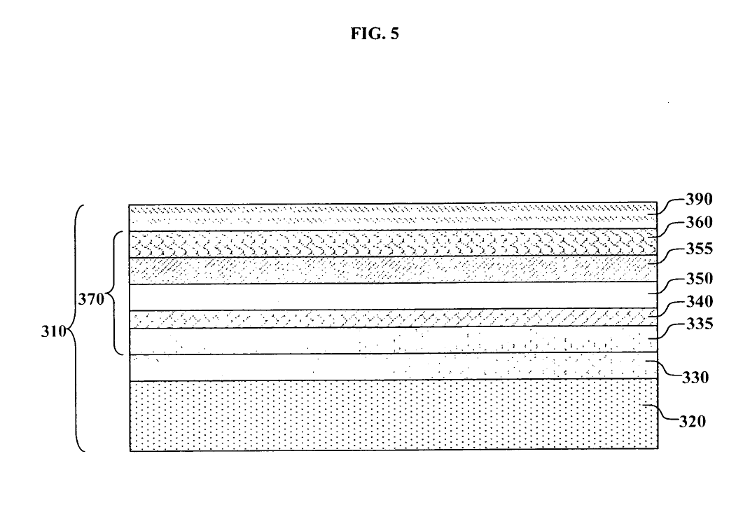

Turning now to FIG. 5, there is shown a cross-sectional view of a pixel of a light-emitting OLED device 310 that is prepared in part according to the present invention. The OLED device 310 includes at a minimum a cathode 390, an anode 330 spaced from cathode 390, and a light-emitting layer 350. The OLED device can also include a substrate 320, a hole-injecting layer 335, a hole-transporting layer 340, an electron-transporting layer 355, and an electron-injecting layer 360. Hole-injecting layer 335, hole-transporting layer 340, light-emitting layer 350, electron-transporting layer 355, and electron-injecting layer 360 comprise a series of organic layers 370 disposed between anode 330 and cathode 390. Organic layers 370 are the organic material layers wherein this invention is used. The organic material described herein is a material used in the formation of any of the above organic layers. The organic material can comprise a single component or is a mixture of two or more different organic components. These components will be described in more detail. The substrate can alternatively be located adjacent to the cathode, or the substrate can actually constitute the anode or cathode. The organic layers between the anode and cathode are conveniently referred to as the organic EL element. The total combined thickness of the organic layers is preferably less than 500 nm.

The present invention is employed in the manufacture of most OLED device configurations. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs). Such TFTs are constructed using amorphous silicon, low temperature polycrystalline silicon, single crystal silicon, other inorganic semiconductors, or organic semiconductor materials.

Substrate

The OLED device of this invention is typically provided over a supporting substrate 320 where either the cathode or anode are in contact with the substrate. The substrate can have a simple or a complex structure with numerous layers, for example, a glass support with electronic elements such as TFT elements, planarizing layers, and wiring layers. The electrode in contact with the substrate is conveniently referred to as the bottom electrode. Conventionally, the bottom electrode is the anode, but this invention is not limited to that configuration. The substrate can either be light transmissive or opaque, depending on the intended direction of light emission. The light transmissive property is desirable for viewing the EL emission through the substrate. Transparent glass or plastic is commonly employed in such cases. For applications where the EL emission is viewed through the top electrode, the substrate is light transmissive, light absorbing or light reflective. Substrates include, but are not limited to, glass, plastic, semiconductor materials, silicon, ceramics, and circuit board materials. Of course it is necessary to provide in these device configurations a light-transmissive top electrode.

Anode

When EL emission is viewed through anode 330, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, are used as the anode. For applications where EL emission is viewed only through the cathode electrode, the transmissive characteristics of anode are immaterial and any conductive material is used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable way such as evaporation, sputtering, chemical vapor deposition, or electrochemical means. Anodes are patterned using well known photolithographic processes. Optionally, anodes can be polished prior to application of other layers to reduce surface roughness so as to reduce shorts or enhance reflectivity.

Hole-lnjecting Layer (HIL)

It is often useful to provide a hole-injecting layer 335 between anode 330 and hole-transporting layer 340. The hole-injecting material can serve to improve the film formation property of subsequent organic layers and to facilitate injection of holes into the hole-transporting layer. Suitable materials for use in the hole-injecting layer include, but are not limited to, porphyrrinic compounds as described in U.S. Pat. No. 4.720,432. plasma-deposited fluorocarbon polymers as described in U.S. Pat. Nos. 6,127,004, 6,208,075, and 6,208,077, some aromatic amines, for example, m-MTDATA (4,4′,4″-tris[(3-methylphenyl)phenyl-amino]triphenylamine), and inorganic oxides including vanadium oxide (VOx), molybdenum oxide (MoOx), and nickel oxide (NiOx). Alternative hole-injecting materials reportedly useful in organic EL devices are described in EP 0 891 121 A1 and EP 1 029 909 A1. Hexaazatriphenylene derivatives are also useful HIL materials, as described in U.S. Pat. No. 6,720,573.

Another class of suitable materials for use in the HIL includes p-type doped organic materials. A p-type doped organic material typically includes a hole-transporting material such as an aromatic amine (see below) that is doped with an electron-accepting dopant. Such dopants can include, for example. 2,3,5,6-tetrafluoro-7,7,8,8-tetracyanoquinodiinethane (F4-TCNQ) and other derivatives of 7,7,8,8-tetracyanoquinodiinethane (TCNQ), and inorganic oxidizing agents such as iodine, FeC13, FeF3, SbC15, some other metal chlorides, and some other metal fluorides. The p-type doped concentration is preferably in the range of 0.01-20 vol. %. Such layers materials are further described in, for example, U.S. Pat. Nos. 5.093,698, 6,423,429, and 6.597,012.

Hole-Transporting Layer (HTL)

The hole-transporting layer 340 contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine is an arylamine, such as a monoarylamine, diarylamine, triarylamine, or a polymeric arylamine. Exemplary monomeric triarylamines are illustrated by Klupfel et al. U.S. Pat. No. 3.180,730. Other suitable triarylamines substituted with one or more vinyl radicals or at least one active hydrogen-containing group are disclosed by Brantley, et al. in U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. The hole-transporting layer is formed of a single or a mixture of aromatic tertiary amine compounds. Illustrative of useful aromatic tertiary amines are the following:

1,1-Bis(4-di-p-tolylaminophenyl)cyclohexane;

1,1-Bis(4-di-p-tolylaminophenyl)-4-phenylcyclohexane;

N,N,N′,N′-tetraphenyl-4,4′″-diamino-1,1′:4′,1″:4″,1′″-quaterphenyl;

Bis(4-dimethylamino-2-methylphenyl)phenylmethane;

1,4-bis[2-[4-[N,N-di(p-toly)amino]phenyl]vinyl]benzene (BDTAPVB);

N,N,N′,N′-Tetra-p-tolyl-4,4′-diaminobiphenyl;

N,N,N′,N′-Tetraphenyl-4,4′-diaminobiphenyl;

N,N,N′,N′-tetra-1-naphthyl-4,4′-diaminobiphenyl;

N,N,N′,N′-tetra-2-naphthyl-4,4′-diaminobiphenyl;

N-Phenylcarbazole;

4,4′-Bis[N-(1-naphthyl)-N-phenylamino]biphenyl(NPB);

4,4′-Bis[N-(1-naphthyl)-N-(2-naphthyl)amino]biphenyl(TNB);

4,4′-Bis[N-(1-naphthyl)-N-phenylamino]p-terphenyl;

4,4′-Bis[N-(2-naphthyl )-N-phenylamino]biphenyl;

4,4′-Bis[N-(3-acenaphthenyl)-N-phenyl amino]biphenyl;

1,5-Bis[N-(1-naphthyl)-N-phenylamino]naphthalene;

4,4′-Bis[N-(9-anthryl)-N-phenylamino]biphenyl;

4,4′-Bis[N-(1-anthryl)-N-phenylamino]-p-terphenyl;

4,4′-Bis[N-(2-phenanthryl)-N-phenylamino]biphenyl;

4,4′-Bis[N-(8-fluoranthenyl)-N-phenylamino]biphenyl;

4,4′-Bis[N-(2-pyrenyl)-N-phenylamino]biphenyl;

4,4′-Bis[N-(2-naphthacenyl)-N-phenylamino]biphenyl;

4,4′-Bis[N-(2-perylenyl)-N-phenylamino]biphenyl:

4,4′-Bis[N-(1-coronenyl )-N-phenylamino]biphenyl;

2,6-Bis(di-p-tolylamino)naphthalene;

2,6-Bis[di-(1-naphthyl)amino]naphthalene;

2,6-Bis[N-(1-naphthyl)-N-(2-naphthyl)amino]naphthalene;

N,N,N′,N′-Tetra(2-naphthyl)-4,4″-diamino-p-terphenyl;

4,4′-Bis{N-phenyl-N-[4-(1-naphthyl )-phenyl]amino}biphenyl;

2,6-Bis[N,N-di(2-naphthyl)amino]fluorene;

4,4′,4″-tris[(3-methylphenyl)phenylamino]triphenylamine(MTDATA); and

4,4′-Bis[N-(3-methylphenyl)-N-phenylamino]biphenyl(TPD).

Another class of useful hole-transporting materials includes polycyclic aromatic compounds as described in EP 1 009 041. Some hole-injecting materials described in EP 0 891 121 A1 and EP 1 029 909 A1 can also make useful hole-transporting materials. In addition, polymeric hole-transporting materials are used including poly(N-vinylcarbazole) (PVK), polythiophenes, polypyrrole, polyaniline, and copolymers including poly(3,4-ethylenedioxy-thiophene)/poly(4-styrenesul fonate) also called PEDOT/PSS.

Light-Emitting Layer (LEL)

As more fully described in U.S. Pat. Nos. 4,769,292 and 5,935,72 1, each of the light-emitting layers (LEL) 350 of the organic EL element include a luminescent fluorescent or phosphorescent material where electroluminescence is produced as a result of electron-hole pair recombination in this region. The light-emitting layer is comprised of a single material, but more commonly contains a host material doped with a guest emitting material or materials where light emission comes primarily from the emitting materials is any color. This guest emitting material is often referred to as a light-emitting dopant. The host materials in the light-emitting layer is an electron-transporting material, as defined below, a hole-transporting material, as defined above, or another material or combination of materials that support hole-electron recombination. The emitting material is typically chosen from highly fluorescent dyes and phosphorescent compounds, e.g., transition metal complexes as described in WO 98/55561, WO 00/1 8851, WO 00/57676, and WO 00/70655. Emitting materials are typically incorporated at 0.01 to 10% by weight of the host material.

The host and emitting materials are small nonpolymeric molecules or polymeric materials including polyfluorenes and polyvinylarylenes. e.g., poly(p-phenylenevinylene), PPV. In the case of polymers, small molecule emitting materials are molecularly dispersed into a polymeric host, or the emitting materials are added by copolymerizing a minor constituent into a host polymer.

An important relationship for choosing an emitting material is a comparison of the bandgap potential which is defined as the energy difference between the highest occupied molecular orbital and the lowest unoccupied molecular orbital of the molecule. For efficient energy transfer from the host to the emitting material, a necessary condition is that the bandgap of the dopant is smaller than that of the host material. For phosphorescent emitters (including materials that emit from a triplet excited state, i.e., so-called “triplet emitters”) it is also important that the host triplet energy level of the host be high enough to enable energy transfer from host to emitting material.

Host and emitting materials known to be of use include, but are not limited to, those disclosed in U.S. Pat. Nos. 4,768,292, 5,141,671. 5,150,006, 5,151,629, 5,405,709, 5,484,922, 5,593,788, 5,645,948, 5,683,823, 5,755,999, 5,928,802, 5,935,720, 5,935,721, 6,020,078, 6,475,648, 6.534,199, 6,661,023, U.S. Patent Application Publications 2002/0127427 A1, 2003/0198829 A1, 2003/0203234 A1, 2003/0224202 A1, and 2004/0001969 A1.

Metal complexes of 8-hydroxyquinoline(oxine) and similar derivatives constitute one class of useful host compounds capable of supporting electroluminescence. Illustrative of useful chelated oxinoid compounds are the following:

CO-1: Aluminum trisoxine[alias, tris(8-quinolinolato)aluminum(III)];

CO-2: Magnesium bisoxine[alias, bis(8-quinolinolato)magnesium(II)];

CO-3: Bis[benzo{f}-8-quinolinolato]zinc (II);

CO-4: Bis(2-methyl-8-quinolinolato)aluminum(II)-m-oxo-bis(2-methyl-8-quinolinolato)aluminum(III);

CO-5: Indium trisoxine[alias, tris(8-quinolinolato)indium];

CO-6: Aluminum tris(5-methyloxine)[alias, tris(5-methyl-8-quinolinolato)aluminum(III)];

CO-7: Lithium oxine[alias, (8-quinolinolato)lithium(I)];

CO-8: Gallium oxine[alias, tris(8-quinolinolato)gallium(III)]; and

CO-9: Zirconium oxine[alias, tetra(8-quinolinolato)zirconium(IV)].

Another class of useful host materials includes derivatives of anthracene, such as those described in U.S. Pat. Nos. 5,935,721, 5,972,247, 6,465,115, 6,534,199, 6,713,192, U.S. Patent Application Publications 2002/0048687, 2003/0072966, and WO 2004/018587. Some examples include derivatives of 9,10-dinaphthylanthracene derivatives and 9-naphthyl -10-phenylanthracene. Other useful classes of host materials include distyrylarylene derivatives as described in U.S. Pat. No. 5,121,029, and benzazole derivatives, for example, 2,2′,2″-(1,3,5-phenylene)tris[1-phenyl-1H-benzimidazole].

Desirable host materials are capable of forming a continuous film. The light-emitting layer can contain more than one host material in order to improve the device's film morphology, electrical properties, light emission efficiency, and lifetime. Mixtures of electron-transporting and hole-transporting materials are known as useful hosts. In addition, mixtures of the above listed host materials with hole-transporting or electron-transporting materials can make suitable hosts.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrylium compounds, fluorene derivatives, periflanthene derivatives, indenoperylene derivatives, bis(azinyl)amine boron compounds, bis(azinyl)methane boron compounds, derivatives of distryrylbenzene and distyrylbiphenyl, and carbostyryl compounds. Among derivatives of distyrylbenzene, particularly useful are those substituted with diarylamino groups, informally known as distyrylamines.

Suitable host materials for phosphorescent emitters (including materials that emit from a triplet excited state, i.e., so-called “triplet emitters”) should be selected so that the triplet exciton is transferred efficiently from the host material to the phosphorescent material. For this transfer to occur, it is a highly desirable condition that the excited state energy of the phosphorescent material be lower than the difference in energy between the lowest triplet state and the ground state of the host. However, the bandgap of the host should not be chosen so large as to cause an unacceptable increase in the drive voltage of the OLED. Suitable host materials are described in WO 00/70655 A2; WO 01/39234 A2; WO 01/93642 A1; WO 02/074015 A2; WO 02/15645 A1, and U.S. Patent Application Publication 2002/0117662. Suitable hosts include certain aryl amines, triazoles, indoles and carbazole compounds. Examples of desirable hosts are 4,4′-N,N′-dicarbazole-biphenyl(CBP), 2,2′-dimethyl-4,4′-N,N′-dicarbazole-biphenyl, m-(N,N′-dicarbazole)benzene, and poly(N-vinylcarbazole), including their derivatives.

Examples of useful phosphorescent materials that are used in light-emitting layers of this invention include, but are not limited to, those described in WO 00/57676, WO 00/70655, WO 01/41512 A1, WO 02/15645 A1, WO 01/93642 A1, WO 01/39234 A2, WO 02/071813 A1, WO 02/074015 A2, U.S. Patent Application Publications 2003/0017361 A1, 2002/0197511 A1, 2003/0072964 A1, 2003/0068528 A1, 2003/0059646 A1, 2003/0054198 A1, 2003/0124381 A1, 2002/0100906 A1, 2003/0068526 A1, 2003/0068535 A1, 2003/0141809 A1, 2003/0040627 A1, 2002/0121638 A1, U.S. Pat. Nos. 6,573,651, 6,451,455, 6,413,656, 6,515,298, 6,451,415, 6,097,147, 6,458,475, EP 1 239 526 A2, EP 1 238 981 A2, EP 1 244 155 A2, JP 2003/073387 A, JP 2003/073388 A, JP 2003/059667 A, and JP 2003/073665 A.

Electron-Transporting Layer (ETL)

Useful thin film-forming materials for use in forming the electron-transporting layer 355 of the organic EL elements of this invention are metal chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary oxinoid compounds were listed previously.

Other electron-transporting materials include various butadiene derivatives as disclosed in U.S. Pat. No. 4,356,429 and various heterocyclic optical brighteners as described in U.S. Pat. No. 4,539,507. Benzazoles, oxadiazoles, triazoles, pyridinethiadiazoles, triazines, phenanthroline derivatives, and some silole derivatives are also useful electron-transporting materials.

Electron-lnjecting Layer (EIL)

To obtain low driving voltage, an n-type doped organic material is to form an electron-injecting layer (EIL) 360 disposed adjacent to the cathode. The EIL is disposed between an ETL and the cathode, or it can also serve the function of the ETL. An n-type doped organic material typically contains an organic electron-transporting material (see above) and an electron-donating dopant such as low work-function metal (<4.0 eV). See, for example, U.S. Pat. Nos. 5,458,977, 6,013,384, 6,509,109, and 6,639,357. Particularly useful electron-transporting materials for use in the EIL include metal chelated oxinoid compounds such as Alq and phenanthroline derivatives. Other useful materials include butadiene derivative, triazines, benzazole derivatives, and silole derivatives. In some instances it is useful to combine two or more hosts to obtain the proper charge injection and stability properties.

Suitable metals for the metal-doped organic layer include alkali metals (e.g. lithium, sodium), alkaline earth metals (e.g. barium, magnesium), or metals from the lanthanide group (e.g. lanthanum, neodymium, lutetium), or combinations thereof. The concentration of the low work-function metal in the metal-doped organic layer is in the range of from 0.1% to 30% by volume. Preferably, the concentration of the low work-function metal in the metal-doped organic layer is in the range of from 0.2% to 10% by volume. Conveniently, the low work-function metal is provided in a mole ratio of about 1:1 with the organic electron transporting material.

Cathode

When light emission is viewed solely through the anode, the cathode 390 used in this invention is comprised of nearly any conductive material. Desirable materials have effective film-fanning properties to ensure effective contact with the underlying organic layer, promote electron injection at low voltage, and have effective stability. Useful cathode materials often contain a low work function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprising a thin electron-injection layer (EIL) in contact with the organic layer (e.g. ETL) that is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861, 5,059,862, and 6,140,763.

When light emission is viewed through the cathode, the cathode should be transparent or nearly transparent. For such applications, metals should be thin or one should use transparent conductive oxides, or includes these materials. Optically transparent cathodes have been described in more detail in U.S. Pat. Nos. 4,885,211, 5,247,190, 5,703,436, 5,608,287, 5,837,391, 5,677,572, 5,776,622, 5,776,623, 5,714,838, 5,969,474, 5,739,545, 5,981,306, 6,137,223, 6,140,763, 6,172,459, 6,278,236, 6,284,393, and EP 1 076 368. Cathode materials are typically deposited by evaporation, sputtering, or chemical vapor deposition. When needed, patterning is achieved through many well known methods including, but not limited to, through-mask deposition, integral shadow masking, for example, as described in U.S. Pat. No. 5,276,380 and EP 0 732 868, laser ablation, and selective chemical vapor deposition.

Other Common Organic Layers and Device Architecture

In some instances, light-emitting layer 350 and electron-transporting layer 355 can optionally be collapsed into a single layer that serves the function of supporting both light emission and electron transportation. It also known in the art that emitting dopants can be added to the hole-transporting layer, which can serve as a host. Multiple dopants can be added to one or more layers in order to produce a white-emitting OLED, for example, by combining blue- and yellow-emitting materials, cyan- and red-emitting materials, or red-, green-, and blue-emitting materials. White-emitting devices are described, for example, in EP 1 187 235, EP 1 182 244, U.S. Pat. Nos. 5,683,823, 5,503,910, 5,405,709, 5,283,132, 6,627,333, U.S. Patent Application Publications 2002/0186214 A1, 2002/0025419 A1, and 2004/0009367 A1.

Additional layers such as exciton, electron and hole-blocking layers as taught in the art can be employed in devices of this invention. Hole-blocking layers are commonly used to improve efficiency of phosphorescent emitter devices, for example, as in U.S. Patent Application Publications 2002/0015859 A1, 2003/0068528 A1, 2003/0175553 A1, WO 00/70655A2, and WO 01/93642A1.

This invention can be used in a so-called tandem device architecture, for example, as taught in U.S. Pat. Nos. 6,337,492, 6,717,358, and U.S. Patent Application Publication 2003/0170491. Such tandem devices have multiple electroluminescent units provided between an anode and a cathode, typically with connector layer between units to promote charge generation and injection into the electroluminescent units.

Deposition of Organic Layers

The organic materials mentioned above are suitably deposited through a vapor-phase method such as sublimation, but is deposited from a fluid, for example, from a solvent with an optional binder to improve film formation. If the material is a polymer, solvent deposition is useful but other methods are used, such as sputtering or thermal transfer from a donor sheet. The material to be deposited by sublimation is vaporized from a sublimation “boat” often comprised of a tantalum material, e.g., as described in U.S. Pat. No. 6,237,529, or is first coated onto a donor sheet and then sublimed in closer proximity to the substrate. Layers with a mixture of materials can use separate sublimation boats or the materials are premixed and coated from a single boat or donor sheet. Patterned deposition is achieved using shadow masks, integral shadow masks (U.S. Pat. No. 5,294,870), spatially-defined thermal dye transfer from a donor sheet (U.S. Pat. Nos. 5,688,551, 5,851,709, and 6,066,357), and inkjet method (U.S. Pat. No. 6,066,357).

Encapsulation

Most OLED devices are sensitive to moisture or oxygen, or both, so they are commonly sealed in an inert atmosphere such as nitrogen or argon. In sealing an OLED device in an inert environment, a protective cover is attached using an organic adhesive, a metal solder, or a low melting temperature glass. Commonly, a getter or desiccant is also provided within the sealed space. Useful getters and desiccants include, alkali and alkaline metals, alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well known optical effects in order to enhance its properties if desired. This includes optimizing layer thicknesses to yield maximum light transmission, providing dielectric mirror structures, replacing reflective electrodes with light-absorbing electrodes, providing anti glare or antireflection coatings over the display, providing a polarizing medium over the display, or providing colored, neutral density, or color conversion filters in functional relationship with the light-emitting areas of the display. Filters, polarizers, and anti-glare or antireflection coatings can also be provided over a cover or as part of a cover.

The OLED device can have a microcavity structure. In one useful example, one of the metallic electrodes is essentially opaque and reflective; the other one is reflective and semitransparent. The reflective electrode is preferably selected from Au, Ag, Mg, Ca, or alloys thereof Because of the presence of the two reflecting metal electrodes, the device has a microcavity structure. The strong optical interference in this structure results in a resonance condition. Emission near the resonance wavelength is enhanced and emission away from the resonance wavelength is depressed. The optical path length is tuned by selecting the thickness of the organic layers or by placing a transparent optical spacer between the electrodes. For example, an OLED device of this invention can have ITO spacer layer placed between a reflective anode and the organic EL media, with a semitransparent cathode over the organic EL media.

This invention can also be applied to inverted OLED structures wherein the cathode is on substrate and the anode is on the top of the device.

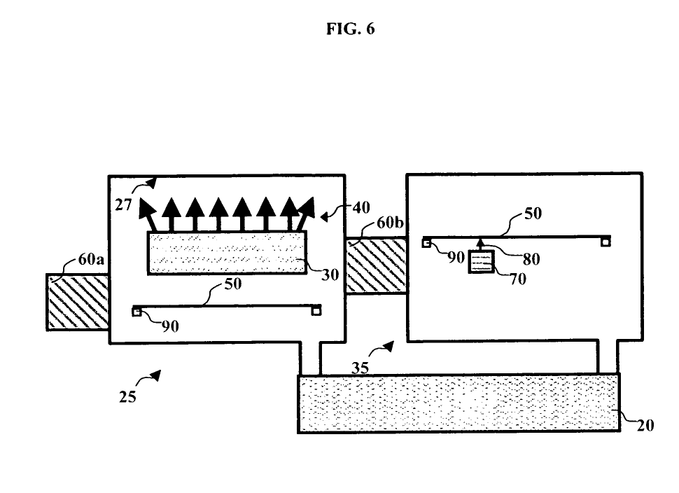

Turning now to FIG. 6, there is shown a cross-sectional view of an embodiment of multiple vacuum chambers and an apparatus that is used in accordance with the present invention. First vacuum chamber 35 and second vacuum chamber 25 are held under vacuum by vacuum pump 20. Second vacuum chamber 25 includes gettering material vaporizer 30 for vaporizing gettering material 40 in the vacuum chamber. Gettering material vaporizer 30 and gettering material 40 are as described above. Gettering material 40 can coat one or more surfaces 27 in second vacuum chamber 25, such as the interior walls of the chamber or a structure provided for receiving gettering material coating within second vacuum chamber 25, as described above.

After gettering material 40 vaporizes and coats surfaces in second vacuum chamber 25, gettering material vaporizer 30 is turned off and a substrate 50 placed in second vacuum chamber 25 via load lock 60a for a predetermined period of time to lessen the level of contaminants in substrate 50. Substrate 50 can then be transferred via load lock 60b to first vacuum chamber 35, where it is coated with organic material 80 from organic material vaporizer 70. After coating with organic material, substrate 50 is moved to second vacuum chamber 25 for a predetermined period of time, wherein the gettering material on the surfaces of second vacuum chamber 25 can react with contaminants to lessen the incorporation of contaminants into the OLED device, before being removed via load lock 60a.

The apparatus can also be part of a larger system similar to that described in FIG. 4 wherein one of the stations is a gettering vacuum chamber, such as second vacuum chamber 25. The substrate can then be placed in the gettering chamber one or more times before, between, or after material deposition steps.

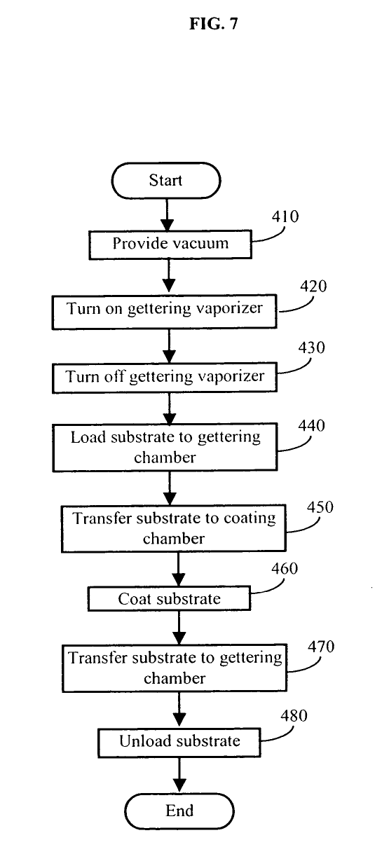

Turning now to FIG. 7, and referring also to FIG. 6, there is shown a block diagram showing the steps involved in another embodiment of a method according to the present invention. At the start, a vacuum condition is provided by vacuum pump 20 in first and second vacuum chambers 35 and 25 (Step 410). Gettering material vaporizer 30 is turned on (Step 420) to vaporize gettering material in second vacuum chamber 25 and coat surfaces in second vacuum chamber 25 with gettering material 40. Gettering material vaporizer 30 is then turned off (Step 430) and a substrate 50 is placed in second vacuum chamber 25 through load lock 60a (Step 440) for a predetermined period of time. Substrate 50 is then transferred to first vacuum chamber 35 (Step 450) via load lock 60b. Organic material 80 is vaporized by organic material vaporizer 70 so as to deposit the vaporized organic material onto substrate 50 and form an organic layer (Step 460). Substrate 50 is then transferred to vacuum chamber 25 (Step 470) for a predetermined period of time. The coated substrate can then be removed from vacuum chamber 25 through load lock 60a (Step 480).

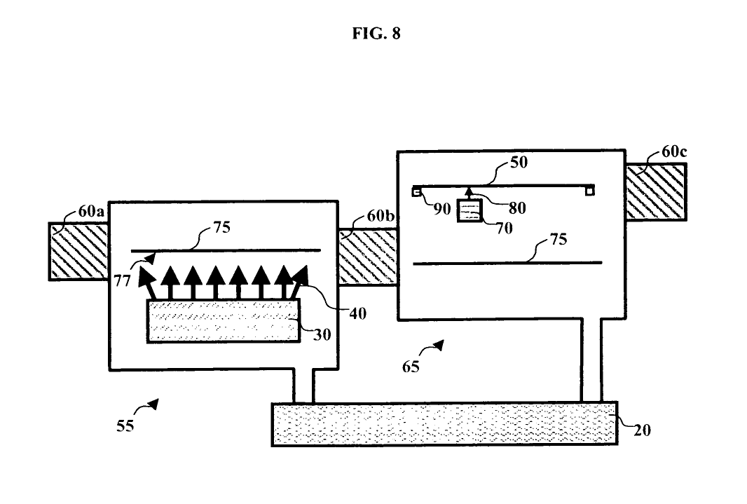

Turning now to FIG. 8, there is shown a cross-sectional view of another embodiment of multiple vacuum chambers and an apparatus that is used in accordance with the present invention. First vacuum chamber 65 and second vacuum chamber 55 are held under vacuum by vacuum pump 20. Second vacuum chamber 55 includes gettering material vaporizer 30 for vaporizing gettering material 40 in the vacuum chamber. Gettering material vaporizer 30 and gettering material 40 are as described above. Mobile member 75 is introduced to second vacuum chamber 55 via load lock 60a and gettering material 40 can coat surface 77 of mobile member 75.

After gettering material 40 vaporizes and coats the surface of mobile member 75, gettering material vaporizer 30 is turned off and mobile member 75, and therefore gettering-coated surface 77, placed in first vacuum chamber 65 via load lock 60b. Substrate 50 is placed in first vacuum chamber 65 via load lock 60c, where it is coated with organic material 80 from organic material vaporizer 70. The presence of gettering-material-coated mobile member 75 acts to react with contaminants from the chamber during the coating process, thereby lessening the incorporation of contaminants into the OLED device prepared from substrate 50. Substrate 50 is left in first vacuum chamber 65 for a further predetermined period of time to further reduce the level of contaminants. After coating with organic material, substrate 50 is removed from vacuum chamber 65 via load lock 60c. If substrate 50 is to be further treated in other chambers to form additional organic layers, mobile member 75 can optionally be carried with it to lessen the incorporation of contaminants in other chambers.

The apparatus can also be part of a larger system similar to that described in FIG. 4 wherein one of the stations is a gettering vacuum chamber, such as second vacuum chamber 55. Mobile members 75 are coated with gettering material at such a station. In one embodiment, a series of such mobile members are distributed to the chambers comprising the other stations of the system, and can remain in the respective stations for the duration of the plate's effectiveness. In another embodiment, a mobile member 75 is coated with gettering material for each substrate 50 to be treated, and is moved from station to station with the substrate.

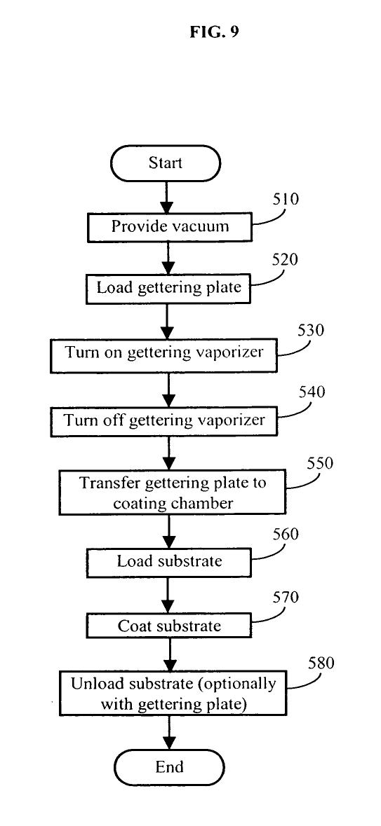

Turning now to FIG. 9, and referring also to FIG. 8 there is shown a block diagram showing the steps involved in another embodiment of a method according to the present invention. At the start, a vacuum condition is provided by vacuum pump 20 in first and second vacuum chambers 65 and 55 (Step 510). Mobile member 75 is loaded into second vacuum chamber 55 via load lock 60a (Step 520). Gettering material vaporizer 30 is turned on (Step 530) to vaporize gettering material in second vacuum chamber 55 and coat surface 77 of mobile member 75 with gettering material 40. Gettering material vaporizer 30 is then turned off (Step 540) and mobile member 75 is transferred to first vacuum chamber 65 through load lock 60b (Step 550). Substrate 50 is introduced to first vacuum chamber 65 (Step 560) via load lock 60c. Organic material 80 is vaporized by organic material vaporizer 70 so as to deposit the vaporized organic material onto substrate 50 and form an organic layer (Step 570). Substrate 50 (optionally with mobile member 75) is then removed from vacuum chamber 65 through load lock 60c (Step 580).

The invention and its advantages is better appreciated by the following comparative examples.

### EXAMPLES

### Example 1 (Comparative)

A comparative OLED device was constructed in the following manner:

1. A clean glass substrate was vacuum-deposited with indium-tin oxide (ITO) to form a transparent electrode of 85 nm thickness.

2. The above-prepared ITO surface was treated with a plasma oxygen etch, followed by plasma deposition of a 2.5 nm layer of a fluorocarbon polymer (CFx) as described in U.S. Pat. No. 6,208,075.

3. The above-prepared substrate was further treated by vacuum-depositing a 150 nm layer of 4,4′-bis[N-(1-naphthyl)-N-phenylamino]biphenyl (NPB) as a hole-transporting layer (HTL) in an organic deposition chamber (Chamber C) of a multi-chamber vacuum cluster tool.

4. A 75 nm electron-transporting layer (ETL) of tris(8-quinolinolato)aluminum(III)(ALQ), which is also an emitting layer, was vacuum-deposited onto the hole-transporting layer (HTL) in the same organic deposition chamber as step 3 (Chamber C) without removing the substrate from the organic deposition chamber between steps 3 and 4.

5. In a different deposition chamber (Chamber E) of the multi-chamber vacuum cluster tool, a 0.5 nm layer of lithium fluoride was evaporatively deposited onto the substrate, followed by a 100 nm layer of aluminum to form a light-transmissive electron-injecting layer and a reflective cathode structure.

### Example 2 (Inventive)

An OLED device was constructed in the manner described in Example 1, except that prior to deposition of the HTL and ETL of steps 3 and 4. lithium getter material was evaporated into Chamber C for 2.5 hr at a rate of 0.055 nm/s. After lithium evaporation, the lithium source was cooled to prevent lithium deposition onto the substrate during HTL and ETL deposition.

### Example 3 (Comparative)

An OLED device was constructed in the manner described in Example 1, except that a different organic deposition chamber (Chamber B) was used for steps 3 and 4.

### Example 4 (Inventive)

An OLED device was constructed in the manner described in Example 3, except that prior to deposition of the HTL and ETL of steps 3 and 4 lithium getter material was evaporated into Chamber B for 2.5 hr at a rate of 0.005-0.035 nm/s. After lithium evaporation, the lithium source was cooled to prevent lithium deposition onto the substrate during HTL and ETL deposition.

### Results (Examples 1-4)

The OLED devices were tested for operational lifetime by operating the OLED devices at an average constant current density of 80 mA/cm² with a 50% duty cycle at 200 Hz and a reverse bias of −14 V. The time for each OLED device to reach 50% of its initial luminance was measured for 2 to 4 replicate OLED devices for each example, and the average time for each example was calculated by averaging the times of the replicate OLED devices. The results are shown in Table 1.

TABLE 1

| | Organic | Li Getter | | Lifetime |
|---|---|---|---|---|
| Example # | Chamber | Pretreatment | Lifetime | Improvement |
| 1(Comparative) | Chamber C | No | 364 hr | — |
| 2(Inventive) | Chamber C | Yes | 528 hr | 45% |
| 3(Comparative) | Chamber B | No | 214 hr | — |
| 4(Inventive) | Chamber B | Yes | 426 hr | 99% |

The results show that treating the organic deposition chambers (Chambers C and B) with a getter material of evaporated lithium before the HTL and ETL coatings improved the lifetime of OLED devices made within those chambers by 45-99%. The amount of improvement is likely to vary based on the level of contamination in the vacuum chamber prior to getter material treatment.

The invention has been described in detail with particular reference to certain preferred embodiments thereof, but it will be understood that variations and modifications can be effected within the spirit and scope of the invention.

### Parts List

10 first vacuum chamber
15 first vacuum chamber
17 surface
20 vacuum pump
25 second vacuum chamber
27 surface
30 gettering material vaporizer
35 first vacuum chamber
40 vaporizing gettering material
45 plate
47 surface
50 substrate
55 second vacuum chamber
60 load lock
60a load lock
60b load lock
60c load lock
65 first vacuum chamber
70 organic material vaporizer
75 mobile member
77 surface
80 organic material
90 support
110 block
120 block
130 block
140 block

### Parts List (con't)

150 block
160 block
170 decision block
180 decision block
200 multi-chamber system
205 first cluster
210 loading station
215 pretreatment station
220 fourth station
225 third station
230 first station
235 emissive layer coating station
240 first robot
245 pass-through
250 second robot
255 orientation station
260 second station
265 vibration isolation element
270 encapsulation station
275 unloading station
280 second cluster
310 OLED device
320 substrate
330 anode
335 hole-injecting layer
340 hole-transporting layer

### Parts List (con't)

350 light-emitting layer
355 electron-transporting layer
360 electron-injecting layer
370 organic layers
390 cathode
410 block
420 block
430 block
440 block
450 block
460 block
470 block
480 block
510 block
520 block
530 block
540 block
550 block
560 block
570 block
580 block

1. A method of vaporizing organic material for deposition of an organic layer on a substrate for use in making an OLED device, comprising:
a) providing a first vacuum chamber;
b) vaporizing gettering material to coat a surface which is in or to be placed in the first vacuum chamber or in a second vacuum chamber; and
c) vaporizing the organic material to deposit vaporized organic material on the substrate and leaving the substrate in the first chamber or moving it to the second chamber, whereby the gettering material reacts with contaminants to lessen incorporation of contaminants into the OLED device.

2. The method according to claim 1 wherein the gettering material includes a reactive metal with a work function of less than 5 eV.

3. The method according to claim 2 wherein the gettering material includes Ti, Al, Sc, Cr, Fe, Ni, Cu, Zn, or Ga, or combinations thereof.

4. The method according to claim 2 wherein the gettering material includes an alkali metal, an alkaline earth metal, or a lanthanide metal.

5. The method according to claim 4 wherein the gettering material includes Li, Cs, Mg, Ca, or Ba, or combinations thereof.

6. The method according to claim 1 wherein the organic material includes mixtures of two or more different organic components.

7. The method according to claim 1 wherein the gettering material is vaporized during the vapor deposition of the organic material.

8. The method according to claim 1 further including one or more chambers for loading, unloading, or transporting the substrate into a corresponding chamber, and wherein gettering material is vaporized in such one or more chambers to coat one or more surfaces to lessen incorporation of contaminants into the OLED device.

9. The method according to claim 1 further including one or more chambers for coating, pretreating, or processing the substrate, and wherein gettering material is vaporized in such one or more chambers to coat one or more surfaces in the chambers to lessen incorporation of contaminants into the OLED device.

10. The method according to claim 1 including providing a mobile member in the second vacuum chamber, coating the surface of the mobile member with gettering material, and placing the coated mobile member in the first vacuum chamber.

11. In a method for making an OLED device, comprising:
a) providing a cluster of two or more vacuum chambers;
b) vaporizing gettering material in one or more of the vacuum chambers to coat surfaces in the vacuum chamber(s); and
c) vaporizing organic material in one or more of the gettering-treated vacuum chambers to deposit vaporized organic material on a substrate and form an organic layer, whereby the gettering material reacts with contaminants in the vacuum chamber to prevent incorporation of contaminants into the organic layer.

12. The method according to claim 11 wherein the gettering material includes a reactive metal with a work function of less than 5 eV.

13. The method according to claim 12 wherein the gettering material includes Ti, Al, Sc, Cr, Fe, Ni, Cu, Zn, or Ga, or combinations thereof.

14. The method according to claim 12 wherein the gettering material includes an alkali metal, an alkaline earth metal, or a lanthanide metal.

15. The method according to claim 14 wherein the gettering material includes Li, Cs, Mg, Ca, or Ba, or combinations thereof.

16. The method according to claim 11 wherein the organic material includes mixtures of two or more different organic components.

17. The method according to claim 11 wherein the gettering material is vaporized during the vapor deposition of the organic material.

18. The method according to claim 11 wherein the cluster of vacuum chambers further includes one or more chambers for loading, unloading, or transporting the substrate into a corresponding chamber, and wherein gettering material is vaporized in such one or more chambers to coat one or more surfaces to lessen incorporation of contaminants into the OLED device.

19. The method according to claim 11 further including one or more chambers for coating, pretreating, or processing the substrate, and wherein gettering material is vaporized in such one or more chambers to coat one or more surfaces to lessen incorporation of contaminants into the OLED device.
